(19) United States
(12) Patent Application Publication
(10) Pub. No.: US 2026/0027495 A1
(43) Pub. Date: Jan. 29, 2026

(54) DISTRIBUTED FILTRATION FOR LIQUID COOLING

(71) Applicant: Mellanox Technologies, Ltd., Yokneam (IL)

(72) Inventors: John Franz, Tomball, TX (US); Tahir Cader, Spokane, WA (US); Matthew Slaby, Beaverton, OR (US)

(73) Assignee: Mellanox Technologies, Ltd., Yokneam (IL)

(21) Appl. No.: 18/783,069

(22) Filed: Jul. 24, 2024

(51) Int. Cl. B01D 29/01; B01D 29/90; B01D 35/26; H05K 7/20

(52) U.S. Cl. CPC B01D 29/016; B01D 29/90; B01D 35/26; H05K 7/20272; H05K 7/20281

(57) ABSTRACT

Filtration units for cooling elements include a fluid-permeable filter element with corrugations, a fluid chamber with an opening to receive a channel arrangement of the cooling element, and one or more flow distribution elements configured to direct fluid from an inlet to the fluid chamber, across the corrugations, and through the channel arrangement to an outlet of the fluid chamber.

### BACKGROUND

Many electronic components, including high-performance computing chips such as graphics processing units (GPUs) and central processing units (CPUs), generate heat during operation. Cooling elements may be utilized with these components to prevent the heat from damaging them.

Liquid-cooled cold plates are one type of computing element. Liquid-cooled cold plates may comprise internal surface elements called micro-channels (similar to the fins found in some types of air-cooled heatsinks). Narrower spacing of micro-channels tends to result in more efficient cooling action.

As micro-channels become narrower they grow more susceptible to clogging from particulates that may be present in the liquid coolant. The liquid-cooled racks and servers in data centers may be supplied with liquid coolant pumped through coolant distribution units. Coolant distribution units may provide centralized filtration, meaning that the liquid coolant for multiple cold plates (e.g., in multiple server systems) is cleaned through a common filter.

Once the coolant passes through the coolant distribution unit's filter, it may suffer a drop in pressure (due to the structure of some typical filters in coolant distribution units) and it may pick up particulates on its way to the racks and cold plates. These particles may clog and reduce the cooling efficiency of the cold plates.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a conventional centralized filtering system.

FIG. 2 depicts a distributed filtering system in one embodiment.

FIG. 3A-FIG. 3C depict an embodiment of a filter filtration unit in top, bottom, and side perspective views.

FIG. 4 depicts an embodiment of a filtration unit 302 in an exploded view.

FIG. 5A and FIG. 5B depict a fluid-permeable filter element in one embodiment.

FIG. 6A and FIG. 6B depict cutaway views of an assembled filtration unit in accordance with one embodiment.

### DETAILED DESCRIPTION

Mechanisms are disclosed to provide distributed filtration co-located with cold plates to address limitations of centralized cold plate filtering. The disclosed mechanisms may capture a high percentages of particles present in liquid coolant circulated through liquid-cooled cold plate by utilizing distributed filters that improve capture of the quantity of particles and that capture particles of smaller size (e.g., <10 um) without incurring the pressure drops found in conventional solutions.

The disclosed distributed filtering mechanisms are scalable and may be integrated with liquid-cooled cold plates to increase filter surface area (e.g, >6×) over approaches that filter centrally at the coolant distribution unit. Particle capture efficiency is improved due to the higher filter surface area, reduced pressure drops, and lower liquid coolant flow velocity than provided be more centralized mechanisms. The disclosed mechanisms also enable the capture of particles that are introduced into the liquid coolant flow downstream of the coolant distribution unit.

In one embodiment, cold plates are adapted to incorporate pleated filters that are replaceable and serviceable in the event of clogging or other issues. The distributed filtering thereby implemented may supplement or replace centralized filtering at a coolant distribution unit.

The filter element may be accessible from underneath a removable cover for replacement if needed. The cover may potentially comprise a transparent plastic material to enable visual inspection of the filter element.

Distribution of filter elements in colocation with cooling elements enables filtration surface area to scale with the number of units (e.g., circuits) being cooled. Further, the flow rate through the filter elements may be significantly reduced over centralized filtration mechanisms at similar pump pressures, due to the larger filtration surface area.

The filter elements utilized in a given deployment may be homogeneous or heterogeneous in their specification (e.g., particle capture capabilities). For example, in a series configuration, the first filter element in a central filter may be configured with a large particle size rating and the localized filter elements may be configured with finer particle capture ratings.

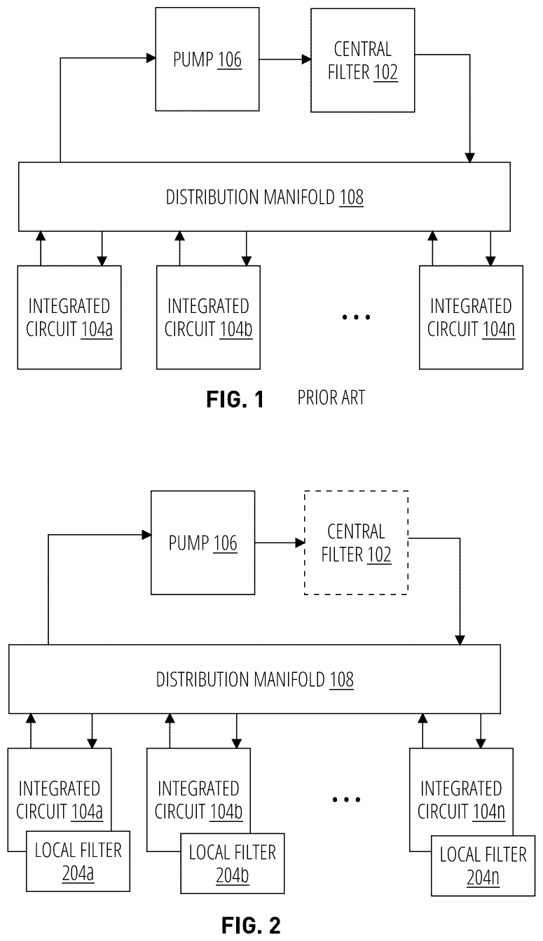

FIG. 1 depicts a conventional centralized filtering system. The system comprises a pump 106 driving pressurized coolant through a central filter 102 to a distribution manifold 108, from which the coolant is distributed to the cooling elements (not depicted) of a number of integrated circuits 104a, 104b, . . . 104n.

FIG. 2 depicts a distributed filtering system in one embodiment. A local filter unit 204a, 204b, . . . 204n is co-located with each of the integrated circuits 104a, 104b, . . . 104n.

Each of the integrated circuits 104a, 104b, . . . 104n may be configured with a cooling element (typically metallic) that includes ‘channels’, which are formations that increase the heat-dissipation surface area of the cooling element. The cooling elements may each be configured with a local filter unit 204a, 204b, . . . 204n that includes a fluid-permeable filter element, and a fluid chamber configured to direct fluid from the fluid pump through a permeable filter and through the channels of the cooling element, as depicted for example in later drawings.

The fluid-permeable filter element may be disposed at an opening of the fluid chamber to facilitate installation and replacement. The fluid chamber may be formed with an opening and cavity to receive the channels of the integrated circuit with which it is configured. Flow distribution elements may be disposed within the fluid chamber between a coolant inlet and a coolant outlet.

Other technical features may be readily apparent to one skilled in the art from the following figures, descriptions, and claims.

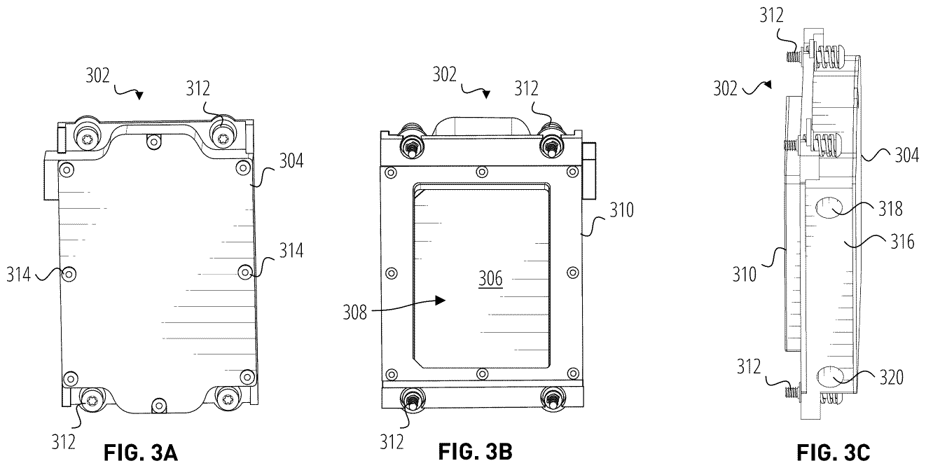

FIG. 3A-FIG. 3C depict an embodiment of a filtration unit 302 in top, bottom, and side perspective views. Herein, references to the “bottom” of the filter unit should be understood to refer to a surface most proximate to the mounting points of the filter unit on a printed circuit board, socket, or integrated circuit. References to the “top” of the filter unit refer to a surface most distal from the mounting points of the filter unit.

The filtration unit 302 comprises an upper cover 304 at the top and a barrier layer 306 at the bottom (visible in FIG. 3B through an opening 308 in a mounting plate 310 to receive a cooling element). Various fasteners 312, 314 may be utilized to mount the filtration unit 302 on a socket, printed circuit board, or integrated circuit and also to join the various components of the filtration unit 302 to one another. The filtration unit 302 further comprises a fluid chamber 316 with an inlet 318 for ingress of pressurized coolant and an outlet 320 for egress of the coolant.

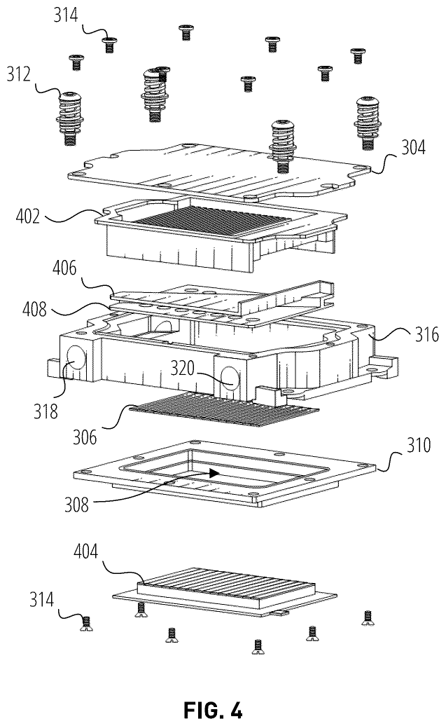

FIG. 4 depicts an embodiment of a filtration unit 302 in an exploded view. The upper cover 304 (which may comprise transparent material) is disposed over a fluid-permeable filter element 402 that is inserted into the fluid chamber 316. A cooling element 404 (e.g., a micro-channel cold plate or heat sink) is received into the opening 308 in the a mounting plate 310. Coolant enters the inlet 318 of the fluid chamber 316 and passes through the fluid-permeable filter element 402 and through formations in the cooling element 404 (herein, “channels”) in a manner formed by flow distribution elements (flow forming plate 406, flow distribution grid 408, and barrier layer 306) before exiting the fluid chamber 316 via the outlet 320.

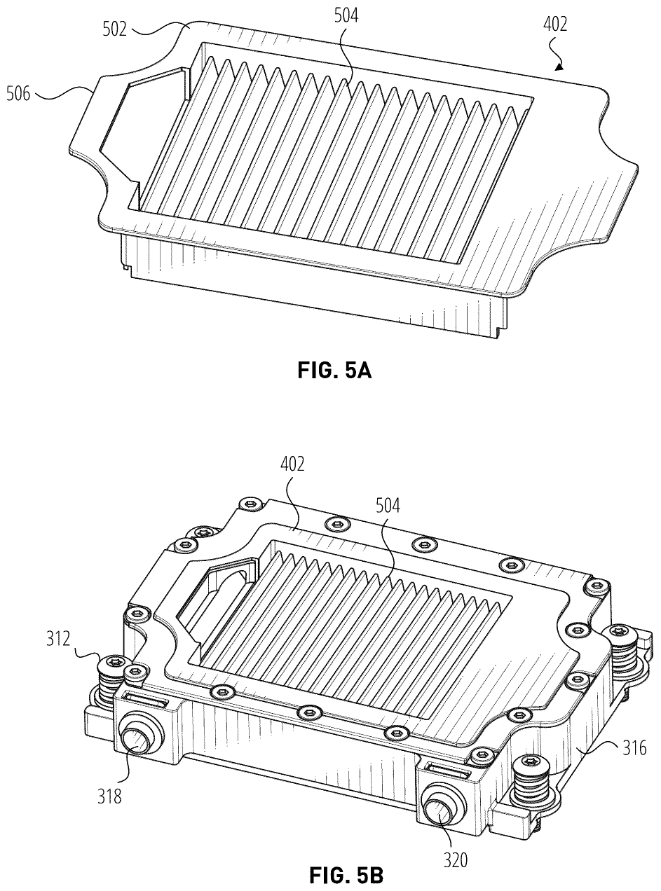

FIG. 5A and FIG. 5B depict a fluid-permeable filter element 402 in one embodiment, comprising a body 502, corrugations 504 (i.e., ‘pleating’), and a handle 506 to facilitate installation and replacement. FIG. 5B depicts the fluid-permeable filter element 402 installed into the fluid chamber 316 of the filtration unit 302. Herein, ‘corrugations’ should be understood to refer to any surface-area enhancing formations of the fluid-permeable material of the filter element.

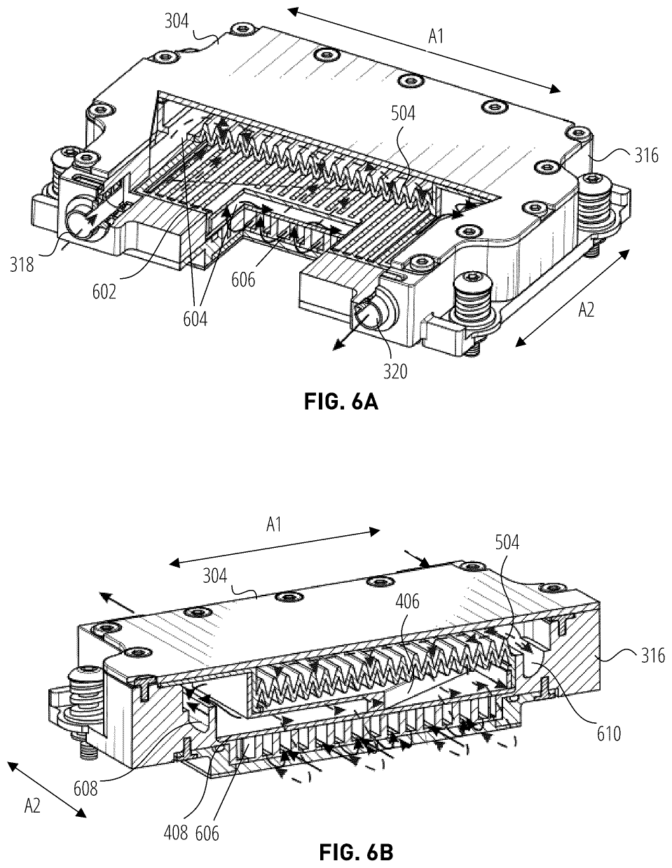

FIG. 6A and FIG. 6B depict cutaway views of an assembled filtration unit in accordance with one embodiment. Coolant enters the inlet 318, traverses an inlet channel 610, and spreads across the corrugations 504 of the fluid-permeable filter element 402. Pressure urges the coolant through a substrate 602 of the fluid-permeable filter element 402, trapping particles. From there the coolant flows over and around the flow distribution elements 604, through the channels 606 of the cooling element 404, and down an outlet channel 608 to the outlet 320 port. Although depicted as right-angled formations the channels 606 of the cooling element 404 may in fact have other shapes and contours in manners known in the art.

The inlet channel 610 and/or outlet channel 608 may be formed to create a pressure differential across the surface of the fluid-permeable filter element 402, e.g., by tapering or otherwise modulating their cross-sections.

The flow distribution elements 604 may be configured to evenly distribute the fluid flow through the channels 606 of the cooling element 404, and/or to evenly distribute particle capture across the fluid-permeable filter element 402 (e.g., to equilibrate coolant pressure across the corrugations 504). In some embodiments, the flow distribution elements 604 may configured to distribute the fluid flow through the channels 606 of the cooling element 404 based on a heat dissipation profile of the integrated circuit to cool, which may result in an uneven flow distribution. The filtration unit may also include where the flow distribution elements comprise a flow forming plate and a flow distribution grid. The filtration unit may also include where the flow distribution elements further comprise a barrier layer.

### LISTING OF DRAWING ELEMENTS

102 central filter
104a integrated circuit
104b integrated circuit
104n integrated circuit
106 pump
108 distribution manifold
204a local filter
204b local filter
204n local filter
302 filtration unit
304 upper cover
306 barrier layer
308 opening
310 mounting plate
312 fastener
314 fastener
316 fluid chamber
318 inlet
320 outlet
402 fluid-permeable filter element
404 cooling element
406 flow forming plate
408 flow distribution grid
502 body
504 corrugations
506 handle
602 substrate
604 flow distribution elements
606 channels
608 outlet channel
610 inlet channel

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A filtration unit for a cooling element, the filtration unit comprising:
a fluid-permeable filter element comprising corrugations;
a fluid chamber comprising an opening to receive a channel arrangement of the cooling element; and
one or more flow distribution elements configured to direct fluid from an inlet to the fluid chamber, across the corrugations, and through the channel arrangement to an outlet of the fluid chamber.

2. The filtration unit of claim 1, wherein the flow distribution elements are configured to evenly distribute particle capture across the corrugations.

3. The filtration unit of claim 1, wherein the flow distribution elements are configured to evenly distribute the fluid flow through the channel arrangement.

4. The filtration unit of claim 1, wherein the flow distribution elements are configured to distribute the fluid flow through the channel arrangement based on a heat dissipation profile of an integrated circuit.

5. The filtration unit of claim 1, wherein the flow distribution elements comprise a flow forming plate and a flow distribution grid.

6. The filtration unit of claim 5, wherein the flow distribution elements further comprise a barrier layer.

7. The filtration unit of claim 1, wherein the flow distribution elements comprise an inlet channel formed to create a pressure differential across the corrugations.

8. The filtration unit of claim 5, configured such that the fluid-permeable filter element is exposed for replacement by removal of a cover plate.

9. A filtration system comprising:
a fluid pump;
a plurality of integrated circuits, each configured with a cooling element comprising channels;
each of the plurality of cooling elements further configured with a filter comprising:
a fluid-permeable filter element; and
a fluid chamber configured to direct fluid from the fluid pump through a permeable filter and through the channels of the cooling element.

10. The filtration system of claim 9, wherein the fluid-permeable filter element is disposed at an opening of the fluid chamber.

11. The filtration system of claim 9, wherein the fluid chamber is formed with a cavity to receive the channels of an integrated circuit with which it is configured.

12. The filtration system of claim 9, further comprising:
each filter comprising a plurality of flow distribution elements configured between an inlet from the fluid pump and an outlet to the fluid pump.

13. The filtration unit of claim 12, wherein the flow distribution elements are configured to evenly distribute the fluid flow through the channels of the cooling element.

14. The filtration unit of claim 12, wherein the flow distribution elements are configured to evenly distribute particle capture across the fluid-permeable filter element.

15. The filtration unit of claim 12, wherein the flow distribution elements are configured to distribute the fluid flow through the channels of the cooling element based on a heat dissipation profile.

16. The filtration unit of claim 12, wherein the flow distribution elements comprise a flow forming plate and a flow distribution grid.

17. The filtration unit of claim 16, wherein the flow distribution elements further comprise a barrier layer.

18. The filtration unit of claim 12, wherein the flow distribution elements comprise an inlet channel formed to create a pressure differential across the corrugations.

19. A method comprising:
pressurizing a fluid flow at a central pump;
directing the fluid flow in parallel to a plurality of filters each fitted over a cooling element disposed on an integrated circuit; and
wherein each filter is configured to direct the fluid flow through a fluid-permeable filter element, through a plurality of flow distribution elements, through channels of the cooling elements, and to a return to the central pump.

20. The method of claim 19, wherein the fluid-permeable filter element is disposed at an access opening of the filter.
